(19) United States
(12) Patent Application Publication
(10) Pub. No.: US 2008/0236615 A1
(43) Pub. Date: Oct. 2, 2008

(54) METHOD OF PROCESSING WAFERS IN A SEQUENTIAL FASHION

(76) Inventors: VICTOR B. MIMKEN, Boise, ID (US); Robert D. Tolles, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/692,791

(22) Filed: Mar. 28, 2007

(51) Int. Cl. H01L 21/02

(52) U.S. Cl. 134/1.3; 134/43

(57) ABSTRACT

A method and apparatus for processing two substrates is provided. The apparatus comprises a chamber having an upper opening, a lower process volume adapted to retain a process solution, and an upper process volume, wherein the chamber is proportioned to vertically process two substrates. The apparatus further comprises a substrate transfer assembly adapted to transfer two substrates in and out of the chamber through the upper opening and one or more megasonic transducers disposed in the chamber, wherein the one or more megasonic transducers are configured to direct megasonic energy towards the process solution retained in the chamber.

### FIELD OF THE INVENTION

Embodiments of the invention as recited by the claims generally relate to the field of surface preparation systems and methods for processing semiconductor substrates and the like. More particularly, embodiments of the invention relate to systems and methods for vertical processing of more than one substrate.

### BACKGROUND OF THE INVENTION

In certain industries there are processes that must be used to bring objects to an extraordinarily high level of cleanliness. For example, in the fabrication of semiconductor substrates, multiple cleaning steps, known as surface preparation, are typically required to remove impurities from the surfaces of the substrates before subsequent processing. A typical surface preparation procedure may include etch, clean, rinse and dry steps. An etch step may involve immersing the substrates in an etch solution of HF to remove surface oxidation and metallic impurities and then thoroughly rinsing the substrates in high purity deionized water (DI) to remove etch chemicals from the substrates. During a typical cleaning step, the substrates are exposed to a cleaning solution that may include water, ammonia or hydrochloric acid, and hydrogen peroxide. After cleaning, the substrates are rinsed using ultra-pure water and then dried using one of several known drying processes.

The effectiveness of a substrate fabrication process is often measured by two related and important factors, which are device yield and the cost of ownership (CoO). These factors are important since they directly affect the cost to produce an electronic device and thus a device manufacturer's competitiveness in the market place. The CoO, while affected by a number of factors, is greatly affected by the system and chamber throughput, or simply the number of substrates per hour processed using a desired processing sequence. In an effort to reduce CoO, electronic device manufacturers often spend a large amount of time trying to optimize the process sequence and chamber processing time to achieve the greatest substrate throughput possible given the tool architecture limitations and the chamber processing times.

Moreover, the push in the industry to shrink the size of semiconductor devices to improve device processing speed and reduce the generation of heat by the device, has reduced the industry's tolerance for process variability. To minimize process variability an important factor in semiconductor fabrication processes is the issue of assuring that every substrate run through a tool sees the same processing conditions or receives the highest quality deposition or cleaning process steps. Conventional batch cleaning processes often do not provide results that are repeatable and uniform for each substrate positioned within the batch or from batch to batch.

For the foregoing reasons, there is a need for a tool that can meet the required device performance goals, has a high substrate throughput, and thus reduces the process sequence CoO.

### SUMMARY OF THE INVENTION

Embodiments of the invention as recited by the claims generally relate to the field of surface preparation systems and methods for processing semiconductor substrates and the like. More particularly, embodiments of the invention relate to systems and methods for vertical processing of more than one substrate.

In certain embodiments a method of sequentially processing two substrates is provided. A process chamber proportioned to vertically process two substrates at a time is filled with a process solution. A first substrate and a second substrate are inserted into the process chamber. The first substrate is swept through a zone of megasonic energy for a cycle. The second substrate is swept through the zone of megasonic energy for a cycle. In certain embodiments, sweeping the first substrate through a zone of megasonic energy comprises extracting the first substrate from the chamber, forming a zone of megasonic energy extending across the process chamber, and re-inserting the first substrate into the process chamber by moving the first substrate through the zone of megasonic energy in an edgewise direction to cause substantially the entire surface of the first substrate to pass through the zone of megasonic energy. In certain embodiments, sweeping the second substrate through a zone of megasonic energy comprises extracting the second substrate from the chamber, forming a zone of megasonic energy extending across the process chamber, and re-inserting the second substrate into the process chamber by moving the second substrate through the zone of megasonic energy in an edgewise direction to cause substantially the entire surface of the second substrate to pass through the zone of megasonic energy.

In certain embodiments a method of sequentially processing two substrates is provided. A process chamber proportioned to vertically process two substrates at a time is filled with a process solution. A first substrate and a second substrate are engaged by a substrate transfer assembly adapted to hold two substrates in a vertical orientation. The first substrate and the second substrate are inserted into the process chamber. The first substrate and the second substrate are disengaged from the substrate transfer apparatus. The first substrate and the second substrate are treated with the process solution. The first substrate is engaged by the substrate transfer assembly. The first substrate is swept through a zone of megasonic energy for a cycle, wherein each cycle comprises extracting the first substrate from the chamber, forming a zone of megasonic energy extending across the process chamber, re-inserting the first substrate into the process chamber by moving the first substrate through the zone of megasonic energy in an edgewise direction to cause substantially the entire surface of the first substrate to pass through the zone of megasonic energy. The first substrate is disengaged from the substrate transfer apparatus. The second substrate is engaged with the substrate transfer apparatus. The second substrate is swept through the zone of megasonic energy for a cycle wherein each cycle comprises extracting the second substrate from the chamber and re-inserting the second substrate into the process chamber by moving the second substrate through the zone of megasonic energy in an edgewise direction to cause substantially the entire surface of the second substrate to pass through the zone of megasonic energy.

In certain embodiments an apparatus for processing two substrates is provided. The apparatus comprises a chamber having an upper opening, a lower process volume adapted to retain a process solution, and an upper process volume, wherein the chamber is proportioned to vertically process two substrates. The apparatus further comprises a substrate transfer assembly adapted to transfer two substrates in and out of the chamber through the upper opening and one or more megasonic transducers disposed in the chamber, wherein the one or more megasonic transducers are configured to direct megasonic energy towards the process solution retained in the chamber. In certain embodiments, the substrate transfer assembly comprises a frame with an actuator adapted to move the substrate transfer assembly in either a vertical or a horizontal direction, two posts extending from the frame, and an end effector formed on an end of each of the two posts, wherein the end effector comprises a first groove adapted to support a first substrate by a bevel edge and a second groove adapted to support a second substrate by a bevel edge. In certain embodiments, the chamber further comprises a first notch coupled to a bottom of the chamber and a second notch coupled to the bottom of the chamber, wherein the first notch is adapted to provide lateral and radial support to a first substrate and the second notch is adapted to provide lateral and radial support to the second substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only certain embodiments and are therefore not to be considered limiting of its scope.

FIG. 1 illustrates a cross-sectional view of an exemplary substrate processing chamber adapted to sequentially process at least two substrates;

FIG. 2 illustrates a perspective view of an exemplary end effector;

FIG. 3 illustrates a plan view of an exemplary processing system incorporating the substrate processing chamber of FIG. 1;

FIG. 4 depicts an exemplary flow diagram of a method of processing two or more substrates; and

FIGS. 5A-5I depicts a simplified diagrammatic representation of an exemplary end effector and substrate processing chamber adapted to sequentially process at least two substrates.

### DETAILED DESCRIPTION

In certain embodiments, chambers for vertically processing two or more substrates and associated processes are disclosed. The chambers and methods of the present invention may be configured to perform wet processing processes, such as for example etching, cleaning, rinsing and/or drying a single substrate. Other exemplary processing chambers may be found in U.S. patent application Ser. No. 10/492,726, filed Dec. 6, 2002, entitled APPARATUS AND METHOD FOR SINGLE OR DOUBLE SUBSTRATE PROCESSING, published as U.S. 2006/0148267, of which FIGS. 9A and 9B and associated text are incorporated herein by reference. Although discussed with reference to a processing chamber adapted to sequentially process two substrates, it should be understood by one of ordinary skill in the art that the apparatus and processes described herein are equally applicable to the processing of more than two substrates.

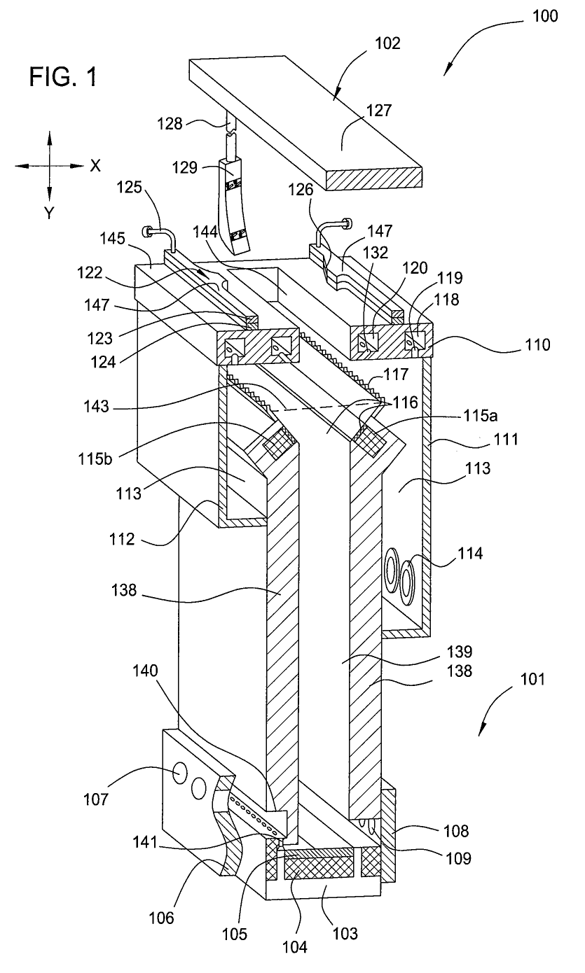

FIG. 1 illustrates a cross sectional view of an exemplary substrate processing chamber 100 for use in accordance with certain embodiments of the present invention. The substrate processing chamber 100 comprises a chamber body 101 adapted to retain two substrate in a liquid and/or a vapor processing environment and a substrate transfer assembly 102 adapted to transfer two substrates in and out the chamber body 101.

The lower portion of the chamber body 101 generally comprises side walls 138 and a bottom wall 103 defining a lower processing volume 139. The lower processing volume 139 may have a rectangular shape configured to retain fluid for immersing a substrate therein. The lower processing volume 139 may be sized to allow for the positioning of two substrates within the processing chamber as well as allowing for the forward and rearward movement of the substrate transfer assembly within the processing chamber as discussed below. A weir 117 is formed on top of the side walls 138 to allow fluid in the lower processing volume 139 to overflow. The upper portion of the chamber body 101 comprises overflow members 111 and 112 configured to collect fluid flowing over the weir 117 from the lower processing volume 139. The upper portion of the chamber body 101 further comprises a chamber lid 110 having an opening 144 formed therein. The opening 144 is adapted to allow the substrate transfer assembly 102 to transfer at least two substrates in and out the chamber body 101. The opening 144 is also adapted to allow for the forward and rearward movement of the substrate transfer assembly 102 within the lower processing volume 139.

An inlet manifold 140 configured to fill the lower processing volume 139 with processing fluid is formed on the sidewall 138 near the bottom of the lower portion of the chamber body 101. The inlet manifold 140 has a plurality of apertures 141 opening to the bottom of the lower processing volume 139. An inlet assembly 106 having a plurality of inlet ports 107 is connected to the inlet manifold 140. Each of the plurality of inlet ports 107 may be connected with an independent fluid source, for example, inlet ports 107 may be connected to a first fluid recirculation circuit (not shown) for supplying HF, for example, to the processing chamber 100. The inlet ports 107 may also be connected to a second fluid recirculation circuit (not shown) for supplying SC1, for example, to each processing chamber 100. Other chemicals for etching, cleaning, and DI water for rinsing, such that different fluids or combination of fluids may be supplied to the lower processing volume 139 for different processes may also be supplied through inlet ports 107.

During processing, fluid may flow in from one or more of the inlet ports 107 to fill the lower chamber volume 139 from the bottom via the plurality of apertures 141. Flow rates for DI water may be between about 1 liters per minute (lpm) and about 60 lpm, such as between about 35 lpm to about 55 lpm for a high flow rate, and about 1 lpm to about 10 lpm for a low flow rate. Standard clean 1 (SC1) may be supplied to the lower chamber volume 139 at a rate between about 15 lpm to about 25 lpm, while an etchant, such as hydrofluoric acid (HF), may be supplied at a rate of about 15 lpm to about 25 lpm.

As the processing fluid fills up the lower processing volume 139 and reaches the weir 117, the processing fluid overflows from the weir 117 to an upper processing volume 113 and is connected by the overflow members 111 and 112. A plurality of outlet ports 114 configured to drain the collected fluid may be formed on the overflow member 111. The plurality of outlet ports 114 may be connected to a pump system. In certain embodiments, each of the plurality of outlet ports 114 may form an independent drain path dedicated to a particular processing fluid. In certain embodiments, each drain path may be routed to a negatively pressurized container to facilitate removal, draining and/or recycling of the processing fluid. In certain embodiments, the overflow member 112 may be positioned higher than the overflow member 111 and fluid collected in the overflow member 112 may flow to the overflow member 111 through a conduit (not shown).

In certain embodiments, a draining assembly 108 may be coupled to the sidewall 138 near the bottom of the lower processing volume 139 and in fluid communication with the lower processing volume 139. The draining assembly 108 is configured to drain the lower processing volume 139 rapidly. In certain embodiments, the draining assembly 108 has a plurality of draining ports 109, each configured to form an independent draining path dedicated to a particular processing fluid. In certain embodiments, each of the independent draining paths may be connected to a negatively pressurized sealed container for fast draining of the processing fluid in the lower processing volume 139. Similar fluid supply and draining configuration may be found in FIGS. 9-10 of U.S. patent application Ser. No. 11/445,707, filed Jun. 2, 2006, which is incorporated herein by reference.

In certain embodiments, a lower megasonic transducer 104 is disposed behind a window 105 in the bottom wall 103. The lower megasonic transducer 104 is configured to provide megasonic energy to the lower processing volume 139. The lower megasonic transducer 104 may comprise a single transducer or an array of multiple transducers, oriented to direct megasonic energy into the lower processing volume 139 via the window 105. When the lower megasonic transducer 104 directs megasonic energy into processing fluid in the lower processing volume 139, acoustic streaming, i.e. streams of microbubbles, within the processing fluid may be induced. The acoustic streaming aids the removal of contaminants from the substrate being processed and keeps the removed particles in motion within the processing fluid hence avoiding reattachment of the removed particles to the substrate surface. The lower megasonic transducer 104 is configured to direct megasonic energy toward a bottom edge of a substrate.

In certain embodiments, a pair of megasonic transducers 115a, 115b, each of which may comprise a single transducer or an array of multiple transducers, are positioned behind windows 116 at an elevation below that of the weir 117, and are oriented to direct megasonic energy into an upper portion of lower processing region 139. The transducers 115a and 115b are configured to direct megasonic energy towards a front surface and a back surface of a substrate respectively.

The transducers 115a and 115b are preferably positioned such that the energy beam interacts with the substrate surface at or just below a gas/liquid interface (will be described below), e.g. at a level within the top 0-20% of the liquid in the lower processing volume 139. The transducers may be configured to direct megasonic energy in a direction normal to the substrate surface or at an angle from normal. Preferably, energy is directed at an angle of approximately 0-30 degrees from normal, and most preferably approximately 5-30 degrees from normal. Directing the megasonic energy from the transducers 115a and 115b at an angle from normal to the substrate surface can have several advantages. For example, directing the energy towards the substrate at an angle minimizes interference between the emitted energy and return waves of energy reflected off the substrate surface, thus allowing power transfer to the solution to be maximized. It also allows greater control over the power delivered to the solution. It has been found that when the transducers are parallel to the substrate surface, the power delivered to the solution is highly sensitive to variations in the distance between the substrate surface and the transducer. Angling the transducers 115a and 115b reduces this sensitivity and thus allows the power level to be tuned more accurately. The angled transducers are further beneficial in that their energy tends to break up the meniscus of fluid extending between the substrate and the bulk fluid (particularly when the substrate is drawn upwardly through the band of energy emitted by the transducers)-thus preventing particle movement towards the substrate surface.

Additionally, directing megasonic energy at an angle to the substrate surface creates a velocity vector towards the weir 117, which helps to move particles away from the substrate and into the weir 117. For substrates having fine features, however, the angle at which the energy propagates towards the substrate front surface must be selected so as to minimize the chance that side forces imparted by the megasonic energy will damage fine structures.

It may be desirable to configure the transducers 115a and 115b to be independently adjustable in terms of angle relative to normal and/or power. For example, if angled megasonic energy is directed by the transducer 115a towards the substrate front surface, it may be desirable to have the energy from the transducer 115b propagate towards the back surface at a direction normal to the substrate surface. Doing so can prevent breakage of features on the front surface by countering the forces imparted against the front surface by the angled energy. Moreover, while a relatively lower power or no power may be desirable against the substrate front surface so as to avoid damage to fine features, a higher power may be transmitted against the back surface (at an angle or in a direction normal to the substrate). The higher power can resonate through the substrate and enhance microcavitation in the trenches on the substrate front, thereby helping to flush impurities from the trench cavities.

Additionally, providing the transducers 115a, 115b to have an adjustable angle permits the angle to be changed depending on the nature of the substrate (e.g. fine features) and also depending on the process step being carried out. For example, it may be desirable to have one or both of the transducers 115a, 115b propagate energy at an angle to the substrate during the cleaning step and then normal to the substrate surface during the drying step. In some instances it may also be desirable to have a single transducer, or more than two transducers, rather than the pair of transducers 115a, 115b.

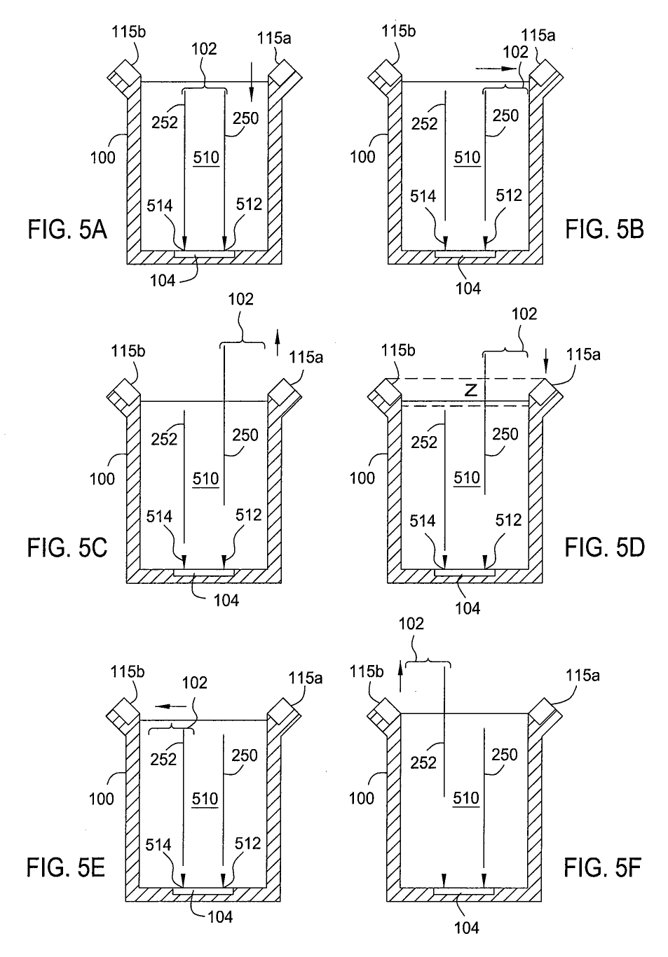

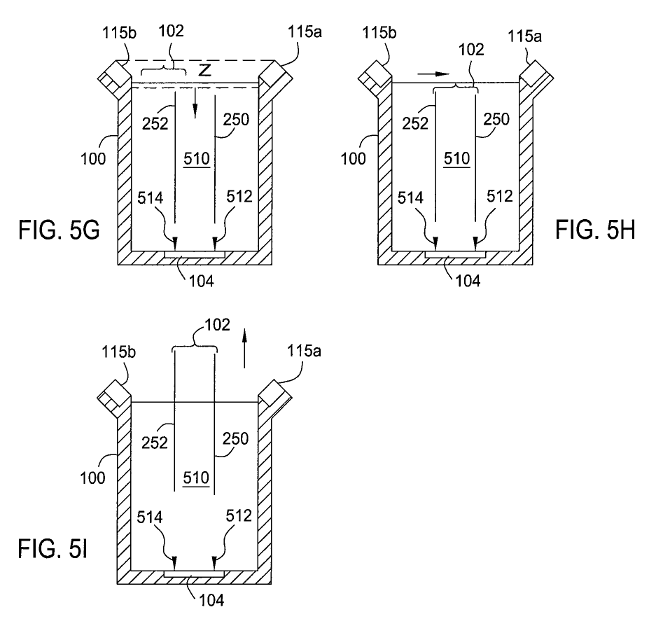

In certain embodiments, the processing chamber 100 contains a first notch (see FIGS. 5A-5I) and a second notch (see FIGS. 5A-5I) attached to the bottom wall 103 of the processing chamber 100. In certain embodiments, the notches may be configured to fully support the substrates against front-to-back and side-to-side movement during processing, and they may work in combination with substrate transfer assembly 102 as discussed below. The first notch and second notch are positioned so as not to block the megasonic energy emitted from the lower megasonic transducer 104 and also to allow for the for and aft movement of the substrate transfer assembly 102 within the process chamber 100.

In certain embodiments, the processing chamber 100 contains a bridge (not shown) supported between the two sidewalls 138, wherein the bridge is adapted to support two substrates. In certain embodiments, the bridge contains a first notch adapted to support a first substrate and a second notch adapted to support a second substrate. The bridge may comprise a material resistive to processing fluids and vapors that may be used in the substrate processing system. In certain embodiments, the bridge is located in the center of the processing chamber 100 supported by the two sidewalls 138. In certain embodiments, the bridge has a narrow profile, for example, the bridge is less than 2 mm wide. In certain embodiments, more than one bridge is positioned between the sidewalls 138 of the processing chamber 100 at different locations, for example, a first bridge contacts the substrate at the four o'clock position, a second bridge contacts the substrate at the six o'clock position, and a third bridge contacts the substrate at the eight o'clock position. The three points of contact on each substrate help maintain planarity of the substrate. The bridge is constructed to have vertical height but a very narrow width to minimize interference with the lower megasonic transducer 102.

In certain embodiments, the chamber lid 110 may have integrated vapor nozzles 132 and exhaust ports 119 for supplying and exhausting one or more vapor into the upper processing volume 113. During process, the lower processing volume 139 may be filled with a processing liquid coming in from the inlet manifold 140 and the upper processing volume 113 may be filled with a vapor coming in from the vapor nozzles 132 on the chamber lid 110. A liquid vapor interface 143 may be created in the chamber body 101. In certain embodiments, the processing liquid fills up the lower processing volume 139 and overflows from the weir 117 and the liquid vapor interface 143 is located at the same level as the weir 117.

During processing, the substrates being processed in the substrate processing chamber 100 are first immersed in the processing liquid in the lower processing volume 139, and then pulled out of the processing liquid. It is desirable that the substrates are free of the processing liquid after being pulled out of the lower processing volume 139. In certain embodiments, the Marangoni effect, i.e. the presence of a gradient in surface tension which naturally causes the liquid to flow away from regions of low surface tension, is used to remove the processing liquid from the substrate. The gradient in surface tension is created at the liquid vapor interface 143. In certain embodiments, an isopropyl alcohol (IPA) vapor is used to create the liquid vapor interface 143. When the substrate is being pulled out from the processing liquid in the lower processing volume 139, the IPA vapor condenses on the liquid meniscus extending between the substrate and the processing liquid. This results in a concentration gradient of IPA in the meniscus, and results in so-called Marangoni flow of liquid from the substrate surface.

As shown in FIG. 1, the opening 144, which is sized to allow for both the forward and rearward movement (e.g. x-direction) of the substrate transfer assembly 102 and the up and down movement (e.g. y-direction) of the substrate transfer assembly 102, relative to the chamber body 101, is formed near a center portion of the chamber lid 110. The integrated vapor nozzles 132 are connected to a pair of inlet channels 120 formed on either side of the opening 144 in the chamber lid 110. In certain embodiments, the vapor nozzles 132 may be formed in an angle such that the vapor is delivered towards the substrate being processed. The exhaust ports 119 are connected to a pair of exhaust channels 118 formed on either side of the opening 144. Each of the inlet channels 120 may be connected to an inlet pipe (not shown) extending from the chamber lid 110. The inlet pipes (not shown) may be further connected to a vapor source. In certain embodiments, the vapor nozzles 132 may be used to supply a gas, such as nitrogen, to the upper processing volume 113. Each of the exhaust channels 118 may be connected to an exhaust pipe (not shown) extending from the chamber lid 110. The exhaust pipes (not shown) may be further connected to a pump system for removing vapor from the upper processing volume 113.

The substrate transfer assembly 102 comprises a pair of posts 128 connected to a frame 127. The frame 127 may be connected with an actuator mechanism adapted to move the substrate transfer assembly 102 both vertically and horizontally as well as forward and backward. An end effector 129 adapted to receive and secure two substrates by their respective edges is connected to a terminal end of each of the posts 128. The end effector 129 is configured to provide lateral and radial support to the substrates while the substrate transfer assembly 102 moves the substrates to and from the chamber body 101.

In certain embodiments, a purge gas may be used following the Marangoni process to remove any residual processing liquid on the substrate. A directed purge assembly 122 may be attached to an upper surface 145 of the chamber lid 110. The directed purge assembly 122 is configured to provide a gas flow to the substrate as the substrate is being removed from the substrate processing chamber 100. The residual fluid retained at the contact region between the end effector and substrate is removed upon exposure to a gas flow delivered from the directed purge assembly 122. The residual fluid may be removed because of the pushing force from the gas flow and/or the drying effect of the gas flow. A variety of gases may be used for the gas flow, for example air, and non-reactive gases, such as nitrogen, argon, carbon dioxide, helium or the combination thereof. In certain embodiments, the gas used in the gas flow may be heated to increase the drying effect.

The directed purge assembly 122 may comprise a pair of nozzle assemblies 147 each positioned on one side of the opening 144 and configured to provide a gas flow to one side of the substrate. Each of the nozzle assembly 147 comprises a bottom member 124 attached to the chamber lid 110 and an upper member 123 attached to the bottom member 124. An inlet port 125 may be connected to each nozzle assembly 147. One or more nozzles 126 in fluid communication with the inlet port 125 may be formed between the bottom member 124 and the upper member 123. The one or more nozzles 126 may be blade shaped, a drilled hole, or an engineered nozzle.

The gas flow from the nozzles 126 may have a flow rate in the range of about 5 liters per minute per nozzle to about 50 liters per minute per nozzle. In certain embodiments, the gas flow rate is about 40 liters per minute per nozzle. When the substrate is being removed from the chamber body 101, the distance between the nozzles 126 to the substrate may be in the range of about 1 mm to about 50 mm. In certain embodiments, the distance between the nozzles 126 to the substrate may be about 15 mm. In another embodiment, the nozzles 126 may be movable so that the distance between the nozzles 126 and the substrates is adjustable to suit different processing requirements. In certain embodiments, the nozzles 126 may be oriented such that the gas flow from the nozzles 126 has an angle of about 15° from a surface of the substrates. In certain embodiments, the gas flow delivered from the nozzles 126 may be horizontal, i.e. parallel to the upper surface 145 of the chamber lid 110.

In operation, after the final treatment and rinse steps are carried out, the substrate is dried within the process chamber 100. Drying may be performed in a number of ways—three of which will be described below. Each of the three examples utilizes an IPA vapor preferably carried into the process chamber 100 by a nitrogen gas flow. In each example, the IPA vapor is preferably generated in an IPA vapor generator, using one of a variety of IPA generation procedures known to those skilled in the art. When the IPA vapor is needed in the process chamber 100, nitrogen gas is passed through a nitrogen supply line into the first IPA vapor generator, and carries the IPA vapor out of the first IPA vapor generator via second supply line to one of the inlet ports 107 in process chamber 100.

The three examples of drying processes using the IPA vapor will next be described. In certain embodiments, the bulk water used for the final rinse may be rapidly discharged from the process chamber 100 by rapidly withdrawing the fluid into a negative pressure container. Then a vapor of isopropyl alcohol is introduced into the process chamber 100 via one of the inlet ports 107. The IPA vapor passes into the lower processing volume 139 of the process chamber 100 and condenses on the surface of the substrate where it reduces the surface tension of the water attached to the substrate, and thus causes the water to sheet off of the substrate surfaces. Any remaining liquid droplets may be evaporated from the substrate surface using gas, such as heated nitrogen gas, introduced through gas inlet port 125. Gas inlet port 125 may include a gas manifold having outlets that are angled downwardly. The end effector 129 may be used to move the substrates past this manifold to accelerate evaporation of remaining PA/water film from the surface of the substrate.

In an alternative drying process, an atmosphere of IPA vapor may be formed in the upper processing volume 113 by introducing the vapor via inlet port 107. According to this embodiment, the substrate transfer assembly 102 lifts the substrate from the lower processing volume 139 into the IPA atmosphere in the upper processing volume 113, where the IPA vapor condenses on the surface of the substrate, causing the surface tension of the water attached to the substrate to be reduced, and thus causing the water to sheet from the substrate surface.

The megasonic transducers 115a, 115b may be energized as the substrate is pulled from the DI water so as to create turbulence in zone Z to thin the boundary layer of fluid attached to the substrate. With the boundary thinned by zone Z, IPA can diffuse more quickly onto the surface of the substrate, thus leading to faster drying with less IPA usage. Thus, the substrate may be withdrawn into the IPA atmosphere relatively quickly, i.e. preferably at a rate of 30 mm/sec or less, and most preferably at a rate of between approximately 8 mm/sec-30 mm/sec. This is on the order of ten times faster than prior extraction drying methods, which utilize a slow withdrawal (e.g. 0.25 to 5 mm/sec) to facilitate a surface-tension gradient between fluid attached to the substrate and the bulk rinse water.

Again, gas such as heated nitrogen may be introduced via nozzles 126 to evaporate any remaining IPA and/or water film, and the substrate may be translated past the nozzles 126 to accelerate this evaporation process.

In a third alternative embodiment, slow extraction-type drying may be utilized. The substrate may thus be slowly drawn from the bulk Di water into the IPA vapor. Using this embodiment, the IPA condenses on the liquid meniscus extending between the substrate and the bulk liquid. This results in a concentration gradient of IPA in the meniscus, and results in so-called Marangoni flow of liquid from the substrate surface. Gas such as heated nitrogen gas may be directed from nozzles 126 onto the substrate to remove some of the residual water and/or IPA droplets and/or film. The substrate may be moved past nozzles 126 to accelerate this evaporation step.

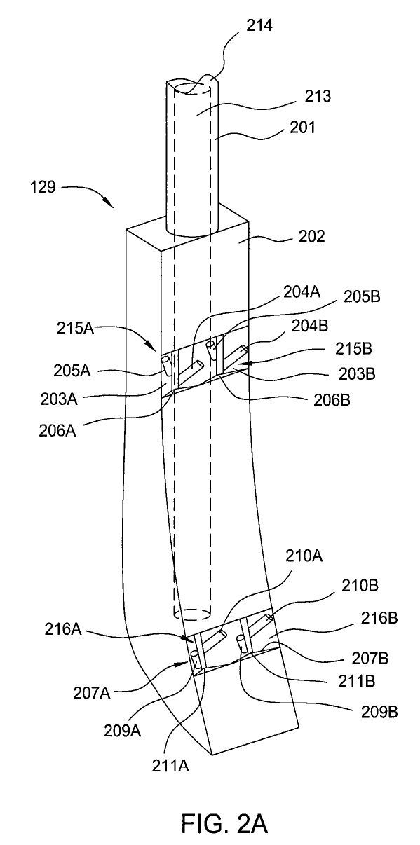

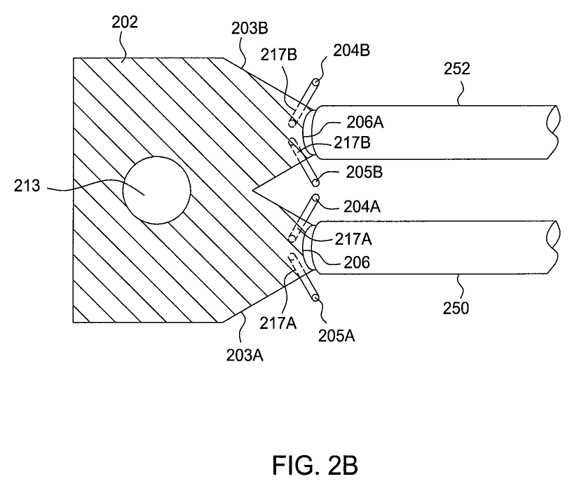

FIG. 2A illustrates a perspective view of an exemplary end effector 129 adapted to support two substrates. FIG. 2B illustrates a sectional view of the end effector 129 of FIG. 2A. The end effector 129 may be used for receiving, supporting and transferring two substrates in a substrate processing system, such as the substrate processing system 100 shown in FIG. 1.

The end effector 129 generally comprises a post 201 adapted for coupling with a substrate transferring mechanism, such as the substrate transfer assembly 102 of the substrate processing system 100. The post 201 may comprise a core 213 made of a rigid material for support and a non-reactive coating 214 protecting the core 213 from processing fluid and vapor. The core 213 may be made from a rigid material, such as metals, for example stainless steel, and hastolloy. In one embodiment, the core 213 may be made from tungsten carbide (WC). The high rigidity of tungsten carbide affords small size for the core 213 which is desirable. The non-reactive coating 214 may be made from a polymer, such as perfluoroalkoxy (PFA). In certain embodiments, the core 213 comprises a ceramic material coated with TEFLON®.

A body 202 is formed on an end of the core 213. The core 213 provides rigid support to the body 202. In one embodiment, a hole may be machined within the body 202 along nearly the entire length of the body 202 for accommodating the core 213 therein. Two sets of contact assemblies 215A and 216A configured to receive and support a first substrate 250 (shown in FIG. 2B) are formed on the body 202. An additional two sets of contact assemblies 215B and 216B configured to receive and support a second substrate 252 (shown in FIG. 2B) are also formed in the body 202. In one embodiment, the body 202 may have a pointy end near the bottom facilitating dripping of processing fluid. The body 202 may be made from a material resistive to processing fluids and vapors that may be used in the substrate processing system.

The body 202 may have a slightly curved shape and have four bases 203A, 203B and 207A, 207B. The contact assemblies 215A and 216A are formed on the bases 203A and 207A respectively. The contact assemblies 215B and 216B are formed on the bases 203B and 207B respectively.

The contact assembly 215A comprises rod members 204A and 205A extending from the base 203A. A first groove 206A is formed between rod members 204A and 205A. As shown in FIG. 2B, the rod members 204A and 205A are secured in holes 217A formed in the base 203A. In one embodiment, the rod members 204A and 205A are replaceable. The rod members 204A and 205A are positioned on opposite sides of the substrate being processed providing guidance and light support to the first substrate 250.

The first groove 206A may be machined to a depth that is similar to or less than the thickness of the substrate 250 being processed therein. In one embodiment, the first groove 206A has a depth between about 0.015 inch and about 0.030 inch. The first groove 206A is configured to provide radial support to the substrate 250 with minimal contact to the substrate.

Similarly, the contact assembly 216A comprises rod members 209A and 210A extending from the base 207A. A second groove 211A is formed between rod members 209A and 210A. The rod members 209A and 210A are secured in holes formed in the base 207A. The rod members 209A and 210A are positioned on opposite sides of the substrate 250 being processed providing guidance and light support to the substrate 250. The second groove 211A may be machined to a depth that is similar to or less than the thickness of the substrate 250 being processed therein. The second groove 211A has a depth between about 0.015 inch and about 0.030 inch. The second groove 211A is configured to provide radial support to the substrate 250 with minimal contact to the substrate.

The additional two sets of contact assemblies 215B and 216B configured to receive and support the second substrate 252 (shown in FIG. 2B) are configured similarly to the first two sets of contact assemblies 215A and 216A. The contact assembly 215B comprises rod members 204B and 205B extending from the base 203B. A third groove 206B is formed between rod members 204B and 205B. As shown in FIG. 2B, the rod members 204B and 205B are secured in holes 217B formed in the base 203B. In one embodiment, the rod members 204B and 205B are replaceable. The rod members 204B and 205B are positioned on opposite sides of the substrate being processed providing guidance and light support to the second substrate 252.

The third groove 206B may be machined to a depth that is similar to or less than the thickness of the substrate 252 being processed therein. In one embodiment, the third groove 206B has a depth between about 0.015 inch and about 0.030 inch. The third groove 206B is configured to provide radial support to the substrate 252 with minimal contact to the substrate.

Similarly, the contact assembly 216B comprises rod members 209B and 210B extending from the base 207B. A fourth groove 211B is formed between rod members 209B and 210B. The rod members 209B and 210B are secured in holes formed in the base 207B. The rod members 209B and 210B are positioned on opposite sides of the substrate 252 being processed providing guidance and light support to the substrate 250. The fourth groove 211B may be machined to a depth that is similar to or less than the thickness of the substrate 252 being processed therein. The fourth groove 211B has a depth between about 0.015 inch and about 0.030 inch. The fourth groove 211B is configured to provide radial support to the substrate 252 with minimal contact to the substrate.

The body 202 and the rod members 204A, 204B, 205A, 205B, 209A, 209B, 210A and 210B may be made from material that is resistive to processing liquids and vapors and does not scratch the substrates being processed. In one embodiment, the body 202 and the rod members 204A, 204B, 205A, 205B, 209A, 209B, 210A and 210B may be made from a polymer, such as PFA, or TEFLON® polymer. In one embodiment, the rod members 204A, 204B, 205A, 205B, 209A, 209B, 210A and 210B may have a diameter of about 0.062 inch.

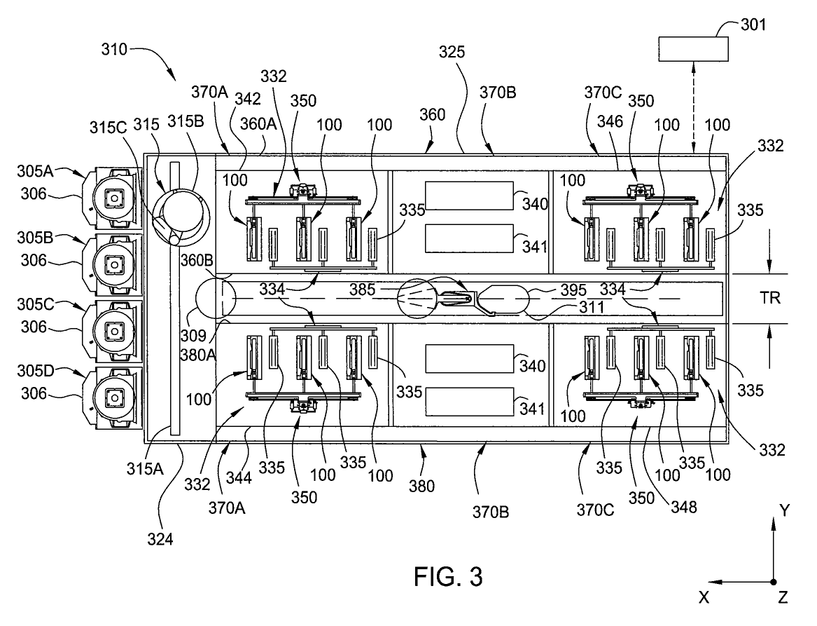

FIG. 3 illustrates a plan view of an exemplary processing system incorporating the substrate processing chamber of FIG. 1. FIG. 3 illustrates a plan view of the processing system 310 that has a first processing rack 360 and a second processing rack 380 each containing two processing chamber arrays 332 that contain a total of three process chambers 100 for a total of six process chambers 100 for each processing rack. In certain embodiments, the processing racks 60 and 80 each contain three modules 370A-370C that either contain processing chambers or supporting equipment. In the configuration shown, modules 370A and 370C each contain three process chambers 100, each grouping of three process chambers is referred to as a cluster, that are positioned along a desirable direction (i.e., X-direction) and module 370B contains the process supporting components, such as the fluid delivery system 340 and other supporting components 341 of the present invention. The first processing rack 360 contains cluster A 342 and cluster C 346. The second processing rack 380 contains cluster B 344 and cluster D 348. The orientation, positioning, type and number of process chambers shown in FIG. 3 are not intended to be limiting as to the scope of the invention, but are intended to illustrate certain embodiments of the invention.

Referring to FIG. 3, in certain embodiments, the front end robot assembly 315 is adapted to transfer substrates between a cassette 306 mounted in a pod assembly 305 (see elements 305A-D) and the one or more of the pass-through positions 309. The front end robot assembly 315 generally contains a horizontal motion assembly 315A and a robot 315B, which in combination are able to position a substrate in a desired horizontal and/or vertical position in the front end module 324 or the adjoining positions in the central module 325. The front end robot assembly 315 is adapted to transfer one or more substrates using one or more robot blades 315C, by use commands sent from a system controller 301. In certain sequences the front end robot assembly 315 is adapted to transfer a substrate from the cassette 306 to the pass-through positions 309. Generally, a pass-through position is a substrate staging area that may contain a pass-through processing chamber that is similar to a conventional substrate cassette 306, which is able to accept one or more substrates from a front end robot 315B so that it can be removed and repositioned by robot assembly 311.

The first robot assembly 311 is adapted to transfer substrates to the various processing chambers contained in the first processing rack 360 and the second processing rack 380. In certain embodiments, as shown in FIG. 3, the substrates are transferred from the robot assembly 311 to a separate actuator assembly 350 that is adapted to position the substrate in a processing chamber 100. In certain embodiments, the modules 370A and 370C each contain a chamber pass-through assembly 334 that is adapted to interface with the robot assembly 311 and the actuator assembly 350.

The system controller 301 is adapted to control the position and motion of the various components used to complete the transferring process. The system controller 301 is generally designed to facilitate the control and automation of the overall system and typically includes a central processing unit (CPU) (not shown), memory (not shown), and support circuits (or I/O) (not shown). The CPU may be one of any form of computer processors that are used in industrial settings for controlling various system functions, chamber processes and support hardware (e.g., detectors, robots, motors, fluid delivery hardware, gas sources hardware, etc.) and monitor the system and chamber processes (e.g., chamber temperature, process sequence throughput, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 301 determines which tasks are performable on a substrate. Preferably, the program is software readable by the system controller 301, which includes code to perform tasks relating to monitoring and execution of the processing sequence tasks and various chamber process recipe steps. Other aspects of the exemplary processing system are discussed in U.S. patent application Ser. No. 11/620,610, filed on Jan. 5, 2007, entitled WET CLEAN SYSTEM DESIGN, which is herein incorporated by reference to the extent not inconsistent with the current specification.

Methods of Operation

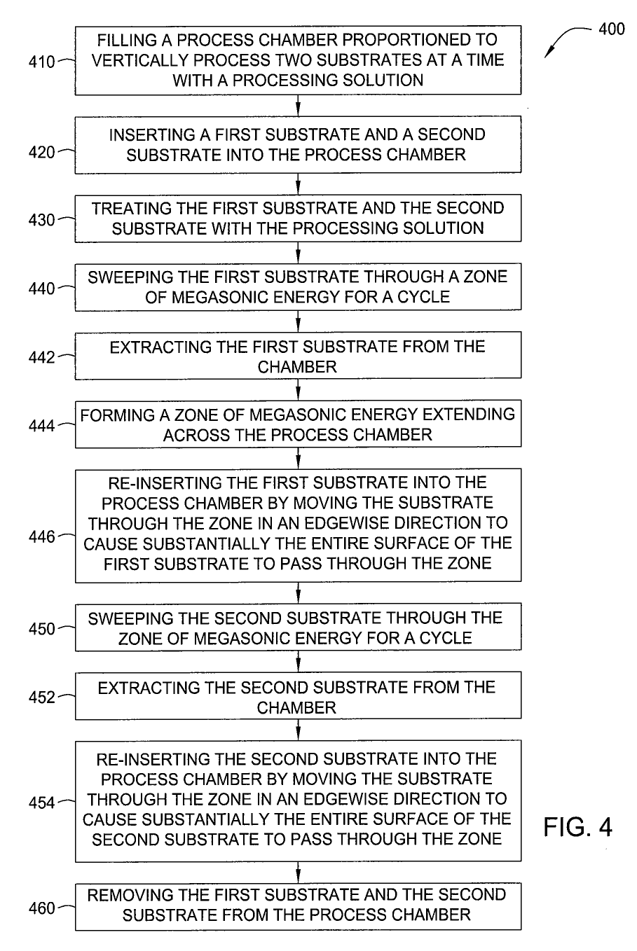

The operation of the substrate transfer assembly 102 with respect to the processing chamber 100 is best described with reference to FIG. 4 and FIGS. 5A-5I. FIG. 4 depicts an exemplary flow diagram of a method 400 of processing two or more substrates. The method 400 may be stored in the memory of a controller, typically as a software routine. The software routine may also be stored and/or executed by a second CPU that is remotely located from the hardware being controlled by the CPU. FIGS. 5A-5I depicts a simplified diagrammatic representation of the substrate transfer assembly 102 and substrate processing chamber 100 adapted to process at least two substrates.

With reference to FIG. 5A and steps 410-430 of FIG. 4, the method 400 begins at step 410 where the lower processing volume 139 of the processing chamber 100 is filled with a processing solution 510. In certain embodiments, the processing solution 510 is a cleaning solution (for example, a solution of water, NH₄OH, and H₂O₂, that is know in the industry as standard clean 1 or “SC1”). In certain embodiments, the processing solution comprises an etchant such as HCl or other solution discussed above. Other etchants, may include, for example, selective etchants and non-selective etchants (NSE), buffered etchants (LAL as one example), and buffered oxide etchants (BOE), among others. Other cleaning solutions may include standard clean 1 (SC1), standard clean 2 (SC2), RCA, an ammonia/peroxide mixture (APM), AM1 chemistry (available from Applied Materials, Inc., of Santa Clara, Calif.), among other cleaning solutions and chemicals.

At step 420 a first substrate 250 and a second substrate 252 are inserted into the process chamber 100 so the first substrate 250 and the second substrate 252 are immersed in the processing solution 510. The first substrate 250 and the second substrate 252 are each coupled with the end effector 129 of the substrate transfer assembly 102 prior to immersion in the processing solution 510. The first substrate 250 is placed in the grooves 206A and 211A of the end effector 129 and the second substrate 252 is placed in the grooves 206B and 211B of the end effector 129. The substrate transfer assembly 102 transfers the first substrate 250 and the second substrate 252 to a first notch 512 and a second notch 514.

The first substrate 250 is placed into the first notch 512 and the second substrate 252 is placed into the second notch 514 both of which are configured to support a substrate both laterally and radially. The first notch 512 and the second notch 514 are coupled to the bottom wall 103 of the processing chamber 100. In certain embodiments, the first notch 512 and the second notch 514 are coupled to the surface of the lower megasonic transducer 104. The first notch and second notch can be V-shaped and can be designed to have the minimal amount of surface area required to support the substrate in order to miminize any obstruction of the lower megasonic transducer 104. In certain embodiments, the first substrate 250 and the second substrate 252 are coupled with a support bridge as described above.

In certain embodiments, the substrate transfer assembly 102 may disengage from the first substrate 250 and the second substrate 252 by moving downward. The rod 128 of the substrate transfer assembly 102 is of a length which allows the substrate transfer assembly 102 to move downward (y-direction) to disengage from the substrate while still maintaining the ability to move forward and backward (x-direction) within the process chamber 100 while the first substrate 250 and the second substrate 252 are disposed in the process chamber 100. The first substrate 250 and the second substrate 252 may be completely immersed in the processing solution 510. In certain embodiments, the first substrate 250 and the second substrate 252 are partially immersed in the processing solution 510.

In certain embodiments, as shown in FIG. 5B, after disengaging from the first substrate 250 and the second substrate 252, the substrate transfer assembly 102 moves to the right so as to position the grooves 206B and 211B of the substrate transfer assembly 102 adjacent the first substrate 250. The first substrate 250 is then engaged by the grooves 206B and 211B of the end effector 129.

At step 440, the first substrate 250 is swept through the zone of megasonic energy for a cycle. In certain embodiments, a “sweep” is performed when a substrate is extracted from the chamber and re-inserted into the chamber through the zone Z of optimum performance. In certain embodiments, a “sweep” is performed when a substrate is extracted from the chamber through the zone of megasonic energy and re-inserted into the chamber through the zone of megasonic energy. In certain embodiments, a “sweep” is performed when a substrate is extracted through the zone of megasonic energy and the megasonics are turned off before re-inserting the substrate into the chamber. In certain embodiments, a “sweep” is performed without the use of megasonic energy. With reference to FIG. 5C and step 442, the substrate transfer assembly 102 extracts the first substrate 250 from the process chamber 100.

With reference to FIG. 5D and step 444, a zone of megasonic energy (z) is formed directly above the processing solution 510. When the upper megasonic transducers 115a, 115b are powered on, the upper transducers form a zone Z of optimum performance. In certain embodiments, this zone Z is a band of megasonic energy extending across the chamber, the zone Z is primarily above the gas/liquid interface and preferably extends slightly below the gas/liquid interface. In certain embodiments, the lower megasonic transducer 104 is also powered on thus contributing megasonic energy to zone Z forming a three phase interface of megasonic energy. In certain embodiments, the area of the zone Z is preferably selected such that when the substrate passes through the zone Z, up to 30 percent of the surface area of a face of the substrate is positioned within the zone. Most preferably, as the center of the substrate passes through the zone, approximately 3-30 percent of the surface area of a face of the substrate is positioned within the band.

The upper transducers 115a, 115b may be configured to direct megasonic energy in a direction normal to the substrate surface as the substrate is inserted into the process chamber 100 or at an angle from normal. In certain embodiments, energy is directed at an angle of approximately 0 degrees to 30 degrees from normal, and most preferably approximately 5 degrees to 30 degrees from normal. In certain embodiments, the upper transducers 115a, 115b are configured to direct megasonic energy at the same angle from normal. In certain embodiments, the first upper transducer 115a is configured to direct energy at a first angle from normal and the second upper transducer 115b is configured to direct energy at a second angle from normal wherein the first angle and the second angle are different.

In certain embodiments, the upper transducers 115a and 115b and the lower transducer 104 are powered on prior to or while extracting the substrate from the process chamber 100 and powered off while re-inserting the substrate into the process chamber 100. In certain embodiments, the upper transducers 115a and 115b and the lower transducer 104 are powered off during the extraction step and powered on prior to the re-insertion step. In certain embodiments, the upper transducers 115a and 115b and the lower transducer 104 are powered off during both the extraction step and the re-insertion step, such as, for example, during an HF etch phase. In certain embodiments, the upper transducers 115a and 115b and the lower transducer 104 are powered on for both the extraction step and the re-insertion step.

In certain embodiments, upon initiation of the “sweep” the upper transducers and the lower transducer are powered on. In certain embodiments, the three transducers are powered to between about 0.04 W/cm² to about 0.2 W/cm² each, such as between about 0.10 W/cm² to about 0.15 W/cm², for example about 0.12 W/cm² each. In certain embodiments, the three transducers are powered off after the extraction step. In certain embodiments, the upper transducers 115a, 115b have different power levels. In certain embodiments, the upper transducers 115a, 115b have the same power level. In certain embodiments, all three transducers have different power levels.

With further reference to FIG. 5D and step 446, the substrate transfer assembly 102 moves vertically downward into the process chamber 100 to re-insert the first substrate 250 into the notch 512 of the process chamber 100 by moving the first substrate 250 through the zone in an edgewise direction to cause substantially the entire surface of the first substrate 250 to pass through the band while substrate 252 remains in the process chamber 100. In certain embodiments, steps 444 and 446 are performed simultaneously. When the wafer is re-inserted into the process chamber 100, the wafer is swept through this zone of optimum performance. The substrate may be translated through the zone to achieve a rate of approximately 25-300 mm/sec, such as between about 100 mm/sec and about 200 mm/sec, for example about 150 mm/sec. In certain embodiments, upon initiation of the “sweep” the upper transducers 115a and 115b and the lower transducer 104 are powered on prior to the re-insertion step 446. In certain embodiments, the upper transducers 115a, 115b and the lower transducer 104 may be powered off prior to the re-insertion step 446. In certain embodiments, the upper transducers 115a and 115b are powered off after the re-insertion step 446 but the lower transducer 104 remains powered on. In certain embodiments, the upper transducers 115a, 115b and the lower transducer 104 remain powered on after the reinsertion step 446.

In certain embodiments, sweeping the first substrate 250 through the zone of megasonic energy Z is performed more than once, for example, between 1 and 20 times, preferably between 2 and 10 times, more preferably between 3 and 5 times.

With reference to FIG. 5E, in certain embodiments, after disengaging from the first substrate 250, the substrate transfer assembly 102 moves to the left so as to position the grooves 206A and 211A of the substrate transfer assembly 102 under the second substrate 252. The second substrate 252 is then engaged by the grooves 206A and 211A of the substrate transfer assembly 102.

At step 450, the first substrate 250 is swept through the zone of megasonic energy for a cycle. A “sweep” is performed when a substrate is extracted from the chamber and inserted into the chamber through the zone Z of optimum performance. With reference to FIG. 5F and step 452, the substrate transfer assembly 102 extracts the first substrate 250 from the process chamber 100.

With reference to FIG. 5G, a zone of megasonic energy (z) is formed directly above the processing solution 510. When the upper megasonic transducers 115a, 115b are powered on, the upper transducers form a zone Z of optimum performance. The zone of megasonic energy (z) may be formed as described above in step 444.

At step 450, the second substrate 252 is swept through the zone of megasonic energy Z for a cycle. At step 454, the second substrate 252 is extracted from the process chamber 100 by moving the second substrate 252 through the zone in an edgewise direction to cause substantially the entire surface of the second substrate 252 to pass through the zone while the first substrate 250 remains in the process chamber 100. As discussed above, in certain embodiments a “sweep” is performed when the second substrate 252 is extracted from the process chamber 100 and inserted into the chamber through the zone Z of optimum performance. When the second substrate 252 is extracted from the chamber, the wafer is swept through this zone of optimum performance. The second substrate 252 may be translated through the zone to achieve a rate of approximately 25-300 mm/sec, such as between about 100 mm/sec and about 200 mm/sec, for example about 150 mm/sec. In certain embodiments, upon initiation of the “sweep” the upper transducers 115a and 115b and the lower transducer 104 are powered on. In certain embodiments, the upper transducers 115a, 115b and the lower transducer 104 may be powered off after the extraction step. In certain embodiments, the upper transducers 115a and 115b are powered off after the extraction step 452 but the lower transducer 104 remains powered on. In certain embodiments, the upper transducers 115a, 115b and the lower transducer 104 remain powered on after the extraction step 452.

With reference to FIG. 5G and step 454, the substrate transfer assembly 102 moves vertically downward into the process chamber 100 to re-insert the second substrate 252 into the second notch 514 of the process chamber 100. In certain embodiments, sweeping the second substrate 252 through the zone of megasonic energy Z is performed more than once.

In certain embodiments, sweeping the second substrate 250 through the zone of megasonic energy Z is performed more than once, for example, between 1 and 20 times, preferably between 2 and 10 times, more preferably between 3 and 5 times.

In certain embodiments, the first substrate 250 and the second substrate 252 may be swept through the zone simultaneously, for example, when performing a process where it is desirable to expose the front side of each substrate to megasonic energy.

With reference to FIG. 5H, the substrate transfer assembly 102 moves to the right so the grooves 206A and 211A are aligned with the first substrate 250 and the grooves 206B and 211B are aligned with the second substrate 252. The first substrate 250 is placed in grooves 206A and 211A of the end effector 129 and the second substrate 252 is placed in the grooves 206B and 211B of the end effector 129. With reference to FIG. 51, at step 460, the first substrate 250 and the second substrate 252 are removed from the process chamber 100.

Thus, the present invention provides methods and apparatus for cleaning substrates that can meet required device performance goals, maintain a high substrate throughput, and reduce the process sequence CoO.

While the foregoing is directed to certain embodiments of the present invention, other and further embodiments of the invention may be devised without departing from the basic scope thereof, and the scope thereof is determined by the claims that follow.

1. A method of sequentially processing two substrates, comprising:
filling a process chamber proportioned to vertically process two substrates at a time with a process solution;
inserting a first substrate and a second substrate into the process chamber;
sweeping the first substrate through a zone of megasonic energy for a first cycle; and
sweeping the second substrate through a zone of megasonic energy for a second cycle.

2. The method of claim 1, wherein sweeping the first substrate through a zone of megasonic energy for a first cycle comprises:
extracting the first substrate from the chamber;
forming the zone of megasonic energy extending across the process chamber; and
re-inserting the first substrate into the process chamber by moving the first substrate through the zone of megasonic energy in an edgewise direction to cause substantially the entire surface of the first substrate to pass thorough the zone of megasonic energy.

3. The method of claim 2, wherein the sweeping the second substrate through a zone of megasonic energy for a second cycle comprises:
extracting the second substrate from the chamber;
forming the zone of megasonic energy extending across the process chamber; and
re-inserting the second substrate into the process chamber by moving the substrate through the zone of megasonic energy in an edgewise direction to cause substantially the entire surface of the second substrate to pass thorough the zone of megasonic energy.

4. The method of claim 1, wherein the sweeping the first substrate through a zone of megasonic energy for a first cycle and the sweeping the second substrate through a zone of megasonic energy for a second cycle occur simultaneously.

5. The method of claim 1, wherein sweeping the first substrate through a zone of megasonic energy for a first cycle comprises:
forming the zone of megasonic energy extending across the process chamber;
extracting the first substrate from the chamber through the zone of megasonic energy; and
re-inserting the first substrate into the process chamber by moving the first substrate through the zone of megasonic energy in an edgewise direction to cause substantially the entire surface of the first substrate to pass thorough the zone of megasonic energy.

6. The method of claim 1, wherein the sweeping the first substrate through a zone of megasonic energy for a first cycle comprises:
forming the zone of megasonic energy extending across the process chamber;
extracting the first substrate from the chamber through the zone of megasonic energy;
eliminating the zone of megasonic energy; and
re-inserting the first substrate into the process chamber.

7. The method of claim 1, wherein the sweeping the first substrate through a zone of megasonic energy for a first cycle comprises:
directing a first megasonic energy toward a front surface of the first substrate; and
directing a second megasonic energy toward a back surface of the first substrate.

8. The method of claim 7, further comprising directing a third megasonic energy in a direction perpendicular to a bottom edge of the first substrate.

9. A method of sequentially processing two substrates, comprising:
filling a process chamber proportioned to vertically process two substrates at a time with a process solution;
engaging a first substrate and a second substrate with a substrate transfer assembly adapted to hold two substrates in a vertical orientation;
inserting the first substrate and the second substrate into the process chamber;
disengaging the first substrate and the second substrate from the substrate transfer apparatus;
treating the first substrate and the second substrate with the process solution;
engaging the first substrate with the substrate transfer apparatus;
sweeping the first substrate through a zone of megasonic energy for a cycle, wherein the cycle comprises:
extracting the first substrate from the chamber;
forming a zone of megasonic energy extending across the process chamber;
re-inserting the first substrate into the processing chamber by moving the first substrate through the zone of megasonic energy in an edgewise direction to cause substantially the entire surface of the first substrate to pass thorough the zone of megasonic energy;
disengaging the first substrate from the substrate transfer apparatus;
engaging the second substrate with the substrate transfer apparatus;
sweeping the second substrate through the zone of megasonic energy for a cycle, wherein the cycle comprises:
extracting the second substrate from the chamber; and
re-inserting the second substrate into the process chamber by moving the substrate through the zone of megasonic energy in an edgewise direction to cause substantially the entire surface of the second substrate to pass thorough the zone of megasonic energy.

10. The method of claim 9, further comprising eliminating the zone of megasonic energy after re-inserting the first substrate into the processing chamber but before the extracting the second substrate from the processing chamber.

11. The method of claim 10, forming a zone of megasonic energy extending across the process chamber after the extracting the second substrate from the processing chamber.

12. The method of claim 9, wherein the process solution is selected from the group comprising water, hydrogen peroxide, ammonium hydroxide, and combinations thereof.

13. The method of claim 9, wherein the forming a zone of megasonic extending across the process chamber, comprises:
directing a first megasonic energy toward a front surface of the first substrate;
directing a second megasonic energy toward a back surface of the first substrate; and
directing a third megasonic energy in a direction perpendicular to a bottom edge of the first substrate.

14. The method of claim 13, wherein the first megasonic energy, the second megasonic energy, and the third megasonic energy are powered to between about between about 0.04 W/cm² to about 0.2 W/cm² each.

15. The method of claim 9, wherein the first substrate is translated through the zone of megasonic energy at a rate of between about 25 mm/sec to about 300 mm/second.

16. The method of claim 15, wherein the substrate is translated through the zone of megasonic energy at a rate of between about 150 mm/sec to about 200 mm/sec.

17. The method of claim 11, wherein the first megasonic energy and the second megasonic energy are propagated at an angle that is less than normal to the surface of the substrate.

18. An apparatus for processing a substrate, comprising:
a chamber having an upper opening, a lower process volume adapted to retain a process solution, and an upper process volume, wherein the chamber is proportioned to vertically process two substrates;
a substrate transfer assembly adapted to transfer two substrates in and out of the chamber through the upper opening; and
one or more megasonic transducers disposed in the chamber, wherein the one or more megasonic transducers are configured to direct megasonic energy towards the process solution retained in the chamber.

19. The apparatus of claim 18, wherein the substrate transfer assembly comprises:
a frame connected with an actuator adapted to move the substrate in either a vertical or a horizontal direction;
two posts extending from the frame; and
an end effector formed on an end of each of the two posts, wherein the end effector comprises a first groove adapted to support a first substrate by a bevel edge and a second groove adapted to support a second substrate by a bevel edge.

20. The apparatus of claim 18, wherein the chamber further comprises a first notch coupled to the bottom of the chamber and a second notch coupled to the bottom of the chamber, wherein the first notch is adapted to provide lateral and radial support to a first substrate and the second notch is adapted to provide lateral and radial support to a second substrate.
